(19) United States
(12) Patent Application Publication
(10) Pub. No.: US 2015/0270450 A1
(43) Pub. Date: Sep. 24, 2015

(54) SEMICONDUCTOR LIGHT-EMITTING DEVICE

(71) Applicant: KABUSHIKI KAISHA TOSHIBA, Tokyo (JP)

(72) Inventors: Toshihiro KUROKI, Nonoichi Ishikawa (JP); Masahiro OGUSHI, Nonoichi Ishikawa (JP)

(21) Appl. No.: 14/337,910

(22) Filed: Jul. 22, 2014

(30) Foreign Application Priority Data
Mar. 19, 2014 (JP) 2014-057240

(51) Int. Cl. H01L 33/50; H01L 33/62; H01L 33/58; H01L 33/60; H01L 33/48; H01L 33/56

(52) U.S. Cl. CPC H01L 33/502; H01L 33/486; H01L 33/56; H01L 33/58; H01L 33/60; H01L 33/62; H01L 2933/0041; H01L 2933/0033

(57) ABSTRACT

A semiconductor light-emitting device includes a light-emitting element provided on a lead frame, a phosphor-containing first resin provided on the light-emitting element and having a first surface facing the light-emitting element, a transparent resin that is provided between the light-emitting element and the phosphor-containing first resin and covering the entirety of the first surface of the phosphor-containing first resin, and a spherical lens provided on the phosphor-containing first resin.

### CROSS-REFERENCE TO RELATED APPLICATION

This application is based upon and claims the benefit of priority from Japanese Patent Application No. 2014-057240, filed Mar. 19, 2014, the entire contents of which are incorporated herein by reference.

### FIELD

Embodiments described herein relate generally to a semiconductor light-emitting device.

### BACKGROUND

A semiconductor device on which a semiconductor light-emitting element such as a light emitting diode (LED) is mounted is used in a backlight of a liquid crystal display or the like.

Surface-mounted semiconductor light-emitting devices have a structure in which a semiconductor light-emitting element is fixed to a lead frame and sealed by resin or the like. LED devices of this type may be referred to as “surface-mounting type” devices or “surface-mounted devices” (SMD). In these devices, light generated by the semiconductor light-emitting element will generally strike the lead frame and/or the substrate on which the semiconductor light-emitting element is formed or mounted. The light which strikes the lead frame or substrate will often result in light absorption (loss) and thus reduce the apparent output (extraction) efficiency of the LED. It is desirable for the light absorption losses in the semiconductor light-emitting device to be small from the viewpoint of light extraction efficiency.

### DESCRIPTION OF THE DRAWINGS

FIG. 1 is a cross-sectional view of a semiconductor light-emitting device according to a first embodiment.

FIG. 2 is a cross-sectional view of a semiconductor light-emitting element and a resin in a portion of the semiconductor light-emitting device according to the first embodiment.

### DETAILED DESCRIPTION

Embodiments provide a semiconductor light-emitting device having improved light extraction efficiency.

In general, according to one embodiment, there is provided a semiconductor light-emitting device including a light-emitting element provided on a lead frame, a phosphor-containing first resin provided on the light-emitting element and having a first surface facing the light-emitting element, a transparent resin that is provided between the light-emitting element and the phosphor-containing first resin and covers the entire first surface of the phosphor-containing first resin, and a spherical lens provided on the phosphor-containing first resin.

Embodiments will be described with reference to the drawings. In this description, common reference symbols are attached to common portions throughout the drawings. It should be noted that that the drawings are schematic and, as such, the depicted dimensional ratio(s) of elements in the drawings do not necessarily reflect the dimensional ratio of elements in actual devices. The drawings are for purposes of general explanation, and those of ordinary skill in the art will recognize the present disclosure not limited devices incorporating dimensional ratios shown in the drawings. In addition, the present disclosure is not limited to the specific example embodiments described herein.

### First Embodiment

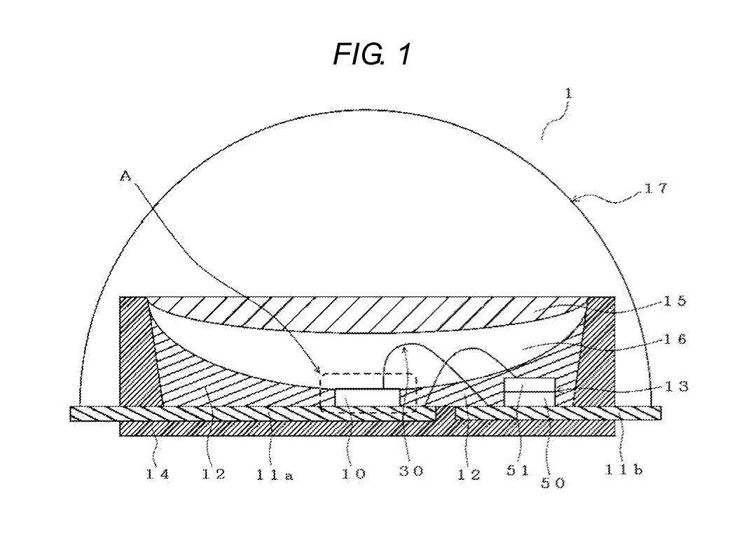

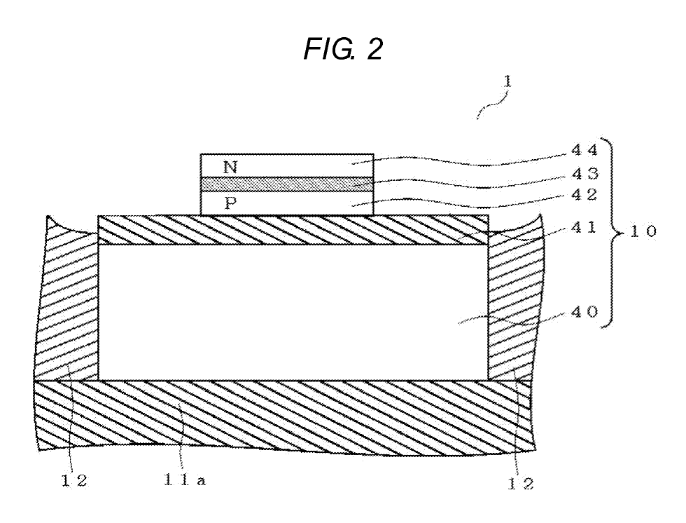

A semiconductor light-emitting device 1 according to a first embodiment will be described with reference to FIGS. 1 and 2. FIG. 1 is a cross-sectional view of the semiconductor light-emitting device 1. FIG. 2 is a cross-sectional view of a semiconductor light-emitting element 10 and a resin 12 in a portion of the semiconductor light-emitting device 1 labeled “A” in FIG. 1.

The semiconductor light-emitting device 1 includes the semiconductor light-emitting element (light-emitting element) 10, a lead frame (installation section) 11a, a lead frame (installation section) 11b, the resin (light reflecting material) 12, a Zener diode (protection element) 13, a sealing resin 14, a phosphor-containing resin 15, a transparent resin 16, a lens 17, and a wire 30. The semiconductor light-emitting element 10 includes a silicon substrate 40, a metal layer (light reflecting material) 41, a P-type semiconductor layer 42, a light-emitting layer 43, and an N-type semiconductor layer 44.

A configuration of the semiconductor light-emitting element 10 will be described. The metal layer 41 that is a light reflecting layer is provided on the silicon (Si) substrate 40. As depicted, P-type semiconductor layer 42 and the N-type semiconductor layer 44 are provided on the metal layer 41. P-type semiconductor layer 42 and N-type semiconductor layer 44 comprise gallium nitride (GaN). The light-emitting layer 43 is formed between the P-type semiconductor layer 42 and the N-type semiconductor layer 44. The position of the P-type semiconductor layer 42 and the N-type semiconductor layer 44 may be reversed. That is, layer 44 may be the layer closer to the metal layer 41 rather than layer 42 being the layer closer to metal layer 41, as is depicted in FIG. 2.

A silicon substrate 40 is used in the semiconductor light-emitting element 10 according to the example embodiment; however, there is no limitation thereto and other substrate materials may be adopted in other embodiments of the present disclosure.

For the purpose of improving the light extraction efficiency of the semiconductor light-emitting device 1, surfaces of the semiconductor light-emitting element 10 may be roughened (rather than flat as depicted in FIG. 2). That is, for example, the upper surface of semiconductor light-emitting element 10 in FIG. 2 may include a plurality of concave-convex structures for purposes of limiting internal reflections at the upper surface.

The semiconductor light-emitting element 10 can be installed on the lead frame 11a (attached to the surface of the lead frame 11a) using solder (not specifically depicted) or the like. At this time, the silicon substrate 40 of the semiconductor light-emitting element 10 is installed on the lead frame 11a. That is, in the example embodiment, the N-type semiconductor layer 44 forms the upper surface of the semiconductor light-emitting element 10.

The Zener diode 13 is installed on the lead frame 11b using solder (not specifically depicted) or the like. The Zener diode 13 comprises a P-type semiconductor layer 50 and an N-type semiconductor layer 51, which are each made of silicon in this example. As depicted, the Zener diode 13 is installed on the lead frame 11b such that the N-type semiconductor layer 51 forms an upper surface.

The lead frame 11a and the lead frame 11b are formed, for example, of a metal material such as copper and are subjected to plating with silver (Ag) to improve adhesion to the resin 12 which will be described later and also reflectance in some cases.

The Zener diode 13 and the semiconductor light-emitting element 10 are connected to each other in a reverse-parallel manner. Here, gold (Au) or the like is used in the wire 30 for connecting the semiconductor light-emitting element 10 and the Zener diode 13, but silver or other conductive materials may be used to implement the embodiment.

The resin 12 covers the side surface of the silicon substrate 40 leaving the upper surface (N-type semiconductor layer 44) exposed. In this example, the resin 12 may be provided to cover the side surface of the metal layer 41 or the side surface of the N-type semiconductor layer 44. That is, the resin 12 may cover the entire side surface of the semiconductor light-emitting element 10. But, in consideration of light extraction efficiency from the side surface of the semiconductor light-emitting element 10, it is desirable that the side surfaces of the N-type semiconductor layer 44, the light-emitting layer 43, and the P-type semiconductor layer 42 be exposed without being covered by the resin 12.

In addition, the resin 12 is provided on the lead frame 11a and the lead frame 11b to cover the Zener diode 13. The resin 12 is provided on the lead frame 11a and the lead frame 11b relying on surface tension to provide an upper surface 60 of the resin 12 with a curved shaped. For example, the upper surface 60 of the resin 12 is curved in a concave parabolic shape and the semiconductor light-emitting element 10 is positioned proximate to the bottom portion of the concave portion.

In this example, the resin 12 is a mixture of transparent silicone that is a polymeric resin containing silicon with a titania (TiO₂) particulate (filler) as a light reflecting material dispersed therein. In general, the filler need only to reflect light in a relevant portion of the spectrum (e.g., a wavelength of emission of the light-emitting layer 43) and materials other than titania may be used. The filler (e.g., titania) loading level in resin 12 is, for example, 10 w % to 70 w %. While in the example, a resin containing a filler is used in resin 12. However, any material that reflects light may be appropriately applied as resin 12 and a compound material such as a non-conductive metal oxide compound may be used.

The transparent resin 16 is provided on the semiconductor light-emitting element 10 and the resin 12. For example, as illustrated in FIG. 1, the phosphor-containing resin 15 is provided to fill a part of the concave portion of the resin 12. For example, silicone is used in the transparent resin 16, but inorganic materials such as glass may be used to implement the embodiment.

The phosphor-containing resin 15 is provided on the transparent resin 16. For example, as illustrated in FIG. 1, the phosphor-containing resin 15 is provided to further fill the concave portion of the resin 12. While the upper surface of the phosphor-containing resin 15 is exposed, the lead frame 11a, the lead frame 11b, and the resin 12 are sealed by the sealing resin 14. In order to improve the light extraction efficiency of the semiconductor light-emitting device 1, the surface of the phosphor-containing resin 15 may be roughened (not illustrated).

Then, the lens 17 is provided on the phosphor-containing resin 15. The lens 17 has a convex spherical shape in a direction from the semiconductor light-emitting element 10 to the phosphor-containing resin 15. In FIG. 1, the lens 17 has a complete round shape, but may have an oval shape.

Examples of resin that is a base material for the resin 12, the phosphor-containing resin 15, the transparent resin 16 and the lens 17 include a phenyl-based silicone resin, a dimethyl-based silicone resin, and an acrylic resin.

Here, a method of forming the semiconductor light-emitting element 10 will be described. In the method, the P-type semiconductor layer 42 and the N-type semiconductor layer 44 are formed on a growth substrate (for example, a silicon substrate (not illustrated)) by epitaxial growth using a metal organic chemical vapor deposition (MOCVD) method or the like. The P-type semiconductor layer 42 and the N-type semiconductor layer 44 may be also formed using a physical vapor deposition (PVD) method such as sputtering. Then, the metal layer 41 is formed on the P-type semiconductor layer 42 by sputtering or the like, and the silicon substrate 40 is attached to the metal layer 41 and the growth substrate can be removed by wet etching or the like. Then, parts of the N-type semiconductor layer 44, the light-emitting layer 43 and the P-type semiconductor layer 42 are removed by etching and a part of the surface of the metal layer 41 is exposed. A first electrode is formed on the N-type semiconductor layer 44 and a second electrode is formed on the exposed metal layer 41. The semiconductor light-emitting element 10 is formed by the above-described processes.

Next, the operation of the semiconductor light-emitting device 1 will be described. When a voltage is applied to the semiconductor light-emitting element 10 in a forward direction, light is emitted from the light-emitting layer 43. In the semiconductor light-emitting device 1 according to the embodiment, when a positive voltage is applied such that the lead frame 11a that is electrically connected to the P-type semiconductor layer 42 is set as a positive electrode and the lead frame 11b that is electrically connected to the N-type semiconductor layer 44 is set as a negative electrode, the light-emitting layer 43 of the semiconductor light-emitting element 10 emits light. For example, blue light can be emitted from the semiconductor light-emitting element 10.

Some of the light L emitted from the light-emitting layer 43 travels in a downward direction—that is, in a direction toward the silicon substrate 40, but is reflected by the metal layer 41. Thus, some of the initially downwardly directed light can be extracted from the upper surface of the semiconductor light-emitting element 10 without being absorbed by the silicon substrate 40.

The light travelling to the outside of the semiconductor light-emitting device 1 is emitted to the outside (e.g., the air) through the lens 17, and, for example, may undergo wavelength conversion (e.g., from blue light to yellow light). Inside the phosphor-containing resin 15, light is scattered by the phosphor (for example, yellow light) or is reflected at an interface between the phosphor-containing resin 15 and the outside. Some of the light which undergoes the wavelength conversion will be emitted in a 360° range (that is, non-directional emission), and the light which is scattered by the phosphor or which is reflected at the interface between the phosphor-containing resin 15 and the outside travels in the direction of the lead frame 11a or the lead frame 11b. The light L which travels in the direction of the lead frame 11a or the lead frame 11b is reflected at the upper surface 60 of the resin 12 and travels again in a direction outside the semiconductor light-emitting device 1, and will be emitted through the lens 17.

The Zener diode 13 and the semiconductor light-emitting element 10 are connected to each other in a reverse-parallel manner. When a surge current or static electricity flows into the semiconductor light-emitting device 1, the semiconductor light-emitting device 1 is prevented from being destroyed by operation of the Zener diode 13.

In the semiconductor light-emitting device 1 according to the example, as described above, the light which travels in the direction of the lead frame 11a or the lead frame 11b by the reflection inside the phosphor-containing resin 15 is reflected again by the filler in resin 12 and thus can be emitted to the outside of the semiconductor light-emitting device 1. Accordingly, it is possible to prevent the light from being absorbed by the silicon substrate 40 or the Zener diode 13. That is, compared to a semiconductor light-emitting device in which the resin 12 is not provided, light extraction efficiency may be improved in the semiconductor light-emitting device 1. In addition, when the filler concentration proximate to the upper surface 60 of the resin 12 is higher than the filler concentration in resin 12 proximate to the lead frame 11a, the efficiency is remarkably improved.

Further, since resin 12 is curved in a concave parabolic shape, the light may be effectively extracted towards the upper portion of the semiconductor light-emitting element 10. That is, the effect of improving uniformity of the light extraction surface of the semiconductor light-emitting device 1 is achieved.

Moreover, in general, the adhesion between resins materials is higher than the adhesion between the semiconductor and the resins. Therefore, the adhesion between the semiconductor light-emitting element 10 and the phosphor-containing resin 15 may be substantially improved by providing the resin 12. As a result, deterioration in brightness caused by separation between the semiconductor light-emitting element 10 and the phosphor-containing resin 15 or deterioration in the reliability of the semiconductor light-emitting device 1 may be prevented.

When different materials are used such that the linear coefficient of thermal expansion of resin 12 is smaller than that of the phosphor-containing resin 15, a force is applied in a direction in which the phosphor-containing resin 15 compresses the semiconductor light-emitting element 10. As a result, deterioration in brightness caused by separation between the semiconductor light-emitting element 10 and the phosphor-containing resin 15 or deterioration in the reliability of the semiconductor light-emitting device 1 may be prevented.

The light reflectance of silver is about 90%, and the light reflectance of gold is about 60%, at wavelengths of typical concern in LEDs. That is, the light reflectance of silver is higher than the light reflectance of gold in these applications. Therefore, when the wire 30 is made of silver, the light extraction efficiency of the semiconductor light-emitting device 1 may be further improved.

In addition, when different materials are used such that the elastic modulus of the resin 12 is lower than that of the phosphor-containing resin 15, cracking caused by external stress may be prevented and mechanical strength may be improved in semiconductor light-emitting device 1.

Furthermore, since the in the example resin 12 includes titania filler, which is an inorganic material, the thermal conductivity of the resin 12 will generally be higher than that of the phosphor-containing resin 15. Therefore, the heat radiation performance of the semiconductor light-emitting device 1 may be improved.

Moreover, when different materials are used such that the thixotropy (shear thinning behavior) of the resin 12 is higher than that of the phosphor-containing resin 15, the shape of the resin 12 may be stabilized during the application of resin 12. Therefore, since the thick and uniform resin 12 may be applied, a relatively thin and uniform phosphor-containing resin 15 may be used, scatter between the phosphor-containing resin 15 and lens 17 may be prevented and thus, the brightness of the semiconductor light-emitting device 1 may be stabilized.

Since the transparent resin 16 is provided between the semiconductor light-emitting element 10 and the phosphor-containing resin 15, a distance between the semiconductor light-emitting element 10 and the phosphor-containing resin 15 is increased in the semiconductor light-emitting device 1. Thus, it is possible to reduce the amount of light that is scattered or is reflected inside the phosphor-containing resin 15 towards the semiconductor light-emitting element 10. Accordingly, it is possible to reduce the light absorbed by the semiconductor light-emitting element 10 and thereby improve light extraction efficiency. Also, since the distance between the semiconductor light-emitting element 10 and the phosphor-containing resin 15 is increased, the light emitted from the semiconductor light-emitting element 10 is not concentrated on the surface of the phosphor-containing resin 15, but is rather spread and dispersed. Thus, hot spots caused by absorption of light in the phosphor-containing resin 15 may be reduced.

In addition, when the phosphor-containing resin 15 is formed in close proximity to semiconductor light-emitting element 10, light (for example, blue light) relatively intensively strikes the phosphor closer to semiconductor light-emitting element 10, and color variation in the light emitted to the outside may occur as a result (that is, there may be spatial variations in the color of the emitted light across the upper surface of the device). However, in the semiconductor light-emitting device 1, since the transparent resin 16 is provided above the semiconductor light-emitting element 10, the light generated from the semiconductor light-emitting element 10 will more uniformly strike the phosphor-containing resin 15. Therefore, it is possible to prevent color breakup from occurring in the light extracted to the outside of the semiconductor light-emitting device 1.

Furthermore, in the semiconductor light-emitting device 1 according to the embodiment, diffused reflection of light on the surface of the phosphor-containing resin 15 may be prevented by providing the lens 17. The diffused reflection of light on the surface of the phosphor-containing resin 15 is prevented and thus, the light extraction efficiency of the semiconductor light-emitting device 1 may be improved.

Herein, in the semiconductor light-emitting device 1, the effect of the configuration in which a refractive index increases from the lens 17 to the semiconductor light-emitting element 10 will be described. That is, the refractive index of the phosphor-containing resin 15 is larger than the refractive index of the lens 17, and the refractive index of the transparent resin 16 is larger than the refractive index of the phosphor-containing resin 15. When light travels from a material having a small refractive index to a material having a large refractive index, light is more likely to be totally reflected at the interface therebetween. Thus, as described above, the light returning to the semiconductor light-emitting element 10 from the phosphor-containing resin 15 is likely to be totally reflected at each interface, and light extraction efficiency will be improved. The refractive indexes of the transparent resin 16, the phosphor-containing resin 15 and the lens 17 may be changed by adjusting an amount of an additive added to the resin(s) (e.g., silicone) which forms the base resin of these respective components. Further, since it is preferable that a difference between the refractive index of the lens 17 and the refractive index of the air is small from the viewpoint of emitting the light to the air, it is advantageous in that the refractive index of the lens 17 is reduced so that the refractive index of the lens becomes closer to the refractive index of the air (R.I. of air=1 (approximately)).

Further, the refractive index of the phosphor-containing resin 15 may be set to be larger than the refractive index of the lens 17 and the refractive index of the transparent resin 16 may be set to be smaller than the refractive index of the phosphor-containing resin 15. In this case, it is possible to prevent light reflection at the interface between the transparent resin 16 and the phosphor-containing resin 15. That is, the light returning to the semiconductor light-emitting element 10 may be prevented.

Since the optimum lens height is changed in accordance with the content of the phosphor in the phosphor-containing resin 15, the light extraction efficiency of the semiconductor light-emitting device 1 may be changed by changing the radius of the spherical lens 17. When the content (loading) of the phosphor is high in the phosphor-containing resin 15, the center of the circle of the lens 17 is desirably set to the phosphor-containing resin 15. That is the center point of radius of curvature of the spherical lens 17 is located in or on the phosphor-containing resin 15. On the other hand, when the content of the phosphor is low in the phosphor-containing resin 15, the center point of the radius of curvature of the lens 17 is desirably set to the surface of the semiconductor light-emitting element 10 or in or on the transparent resin 16.

As described above, even when inorganic materials such as glass are used as the material of the lens 17, the embodiment may be implemented. From the viewpoint of heat radiation of the semiconductor light-emitting device 1, inorganic materials are more desirable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device comprising:
a light-emitting element on a lead frame;
a first resin including a phosphor, the first resin disposed on the light-emitting element and having a first surface facing the light-emitting element;
a transparent resin between the light-emitting element and the first surface of the first resin and covering the entirety of the first surface; and
a spherical lens on the first resin.

2. The device according to claim 1, wherein the light-emitting element includes:
a substrate;
a light-emitting section disposed on the substrate; and
a first light reflecting material disposed on a second surface of the substrate and between the substrate and the light-emitting section.

3. The device according to claim 2, wherein a second light reflecting material is disposed on a third surface of the substrate that intersects the second surface of the substrate at one of an oblique angle and a right angle.

4. The device according to claim 3, wherein
the first light reflecting material is a metal layer covering the second surface of the substrate, and
the second light reflecting material is a second resin material disposed on the third surface of the substrate.

5. The device according to claim 4, wherein the second resin material contains a filler that reflects light at a wavelength within a wavelength range of at least one of light emitted by the light emitting element and light emitted by the phosphor upon excitation with light emitted by the light emitting element.

6. The device according to claim 5, wherein the filler comprises titanium dioxide.

7. The device according to claim 3, wherein the second light reflecting material has a surface forming a concave parabolic shape and the light-emitting element is disposed at a vertex of the concave parabolic shape.

8. The device according to claim 2, wherein the substrate comprises silicon.

9. The device according to claim 1, wherein
a refractive index of the transparent resin is larger than a refractive index of the first resin, and
a refractive index of a layer in the light-emitting element that is directly adjacent to the transparent resin is larger than the refractive index of the transparent resin.

10. The device according to claim 1, wherein the refractive index of the transparent resin is larger than the refractive indexes of the phosphor-containing resin and the spherical lens.

11. The device according to claim 1, wherein a center point of the radius of curvature of the spherical lens is in the first resin.

12. The device according to claim 1, wherein a center point of the radius of curvature of the spherical lens is in one of the transparent resin and the light-emitting element.

13. A light-emitting device, comprising:
a light-emitting element disposed on a lead frame;
a transparent resin disposed on the light-emitting element such that the light-emitting element is between the lead frame and the transparent resin;
a first resin including a phosphor, the first resin disposed on the transparent resin such that the transparent resin is between the first resin and the light-emitting element; and
a spherical lens disposed on the first resin, wherein a refractive index of the transparent resin is greater than a refractive index of the first resin, and the refractive index of the first resin is greater than a refractive index of the spherical lens.

14. The light-emitting device according to claim 13, further comprising a light reflective material disposed on the lead frame and having an upper surface forming a concave parabolic shape, wherein the light-emitting element is disposed at a vertex of the concave parabolic shape.

15. The light-emitting device according to claim 14, wherein the light reflective material comprises a second resin including a filler.

16. A method of making a light-emitting device, the method comprising:
mounting a light-emitting element on a lead frame;
forming a transparent resin on the light-emitting element such that the light-emitting element is between the transparent resin and the lead frame;
forming a first resin including a phosphor on the transparent resin such that the transparent resin is between the first resin and the light emitting element; and
forming a spherical lens on the first resin, wherein a center point of a radius of curvature of the spherical lens is set according to a loading level of the phosphor in the first resin such that when the loading level is low the center point is in one of the transparent resin and the light-emitting element, and when the loading level is high the center point is in the first resin.

17. The method according to claim 16, wherein a refractive index of the transparent resin is greater than a refractive index of the first resin, and the refractive index of the first resin is greater than a refractive index of the spherical lens.

18. The method according to claim 16, wherein a refractive index of the first resin is greater than a refractive index of the transparent resin.

19. The method according to claim 16, further comprising:
forming a light reflective material on the lead frame to have an upper surface forming a concave parabolic shape, the light-emitting element being disposed at a vertex of the concave parabolic shape.

20. The method according to claim 19, wherein the light reflective material comprises a second resin including a filler.
